(19) United States
(12) Patent Application Publication
(10) Pub. No.: US 2024/0363660 A1
(43) Pub. Date: Oct. 31, 2024

(54) DEEP TRENCH ISOLATION STRUCTURES FOR CMOS IMAGE SENSOR AND METHODS THEREOF

(71) Applicant: OMNIVISION TECHNOLOGIES, INC., Santa Clara, CA (US)

(72) Inventor: Hui Zang, San Jose, CA (US)

(21) Appl. No.: 18/306,517

(22) Filed: Apr. 25, 2023

(51) Int. Cl. H01L 27/146

(52) U.S. Cl. CPC H01L 27/1463; H01L 27/14649; H01L 27/14689

(57) ABSTRACT

A pixel includes a semiconductor substrate having a first side and a second side. Extending from the first side is a first deep trench isolation (DTI) structure and a second DTI structure. The first DTI structure includes a wide portion and a narrow portion extending from the wide portion. A first width of the wide portion is greater than a second width of the narrow portion, and the wide portion extends to a first depth. The pixel further includes a photodiode region disposed in the semiconductor substrate between the first DTI structure and the second DTI structure. A cell deep trench isolation (CDTI) structure is disposed between the wide portion of the first DTI structure and the second DTI structure. The CDTI structure extends to a second depth. The first depth and the second depth extend a substantially equal distance from the first side of the semiconductor substrate.

### BACKGROUND INFORMATION

### Field of the Disclosure

This disclosure relates generally to image sensors, and in particular but not exclusively, relates to complementary metal oxide semiconductor (CMOS) image sensors with near infrared light sensitivity.

### Background

Image sensors have become ubiquitous and are now widely used in digital cameras, cellular phones, security cameras, as well as medical, automobile, and other applications. As image sensors are integrated into a broader range of electronic devices, it is desirable to enhance their functionality, performance metrics, and the like in as many ways as possible (e.g., resolution, power consumption, dynamic range, etc.) through both device architecture design as well as image acquisition processing.

A typical image sensor operates in response to image light from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bitlines that vary as a function of the incident image light. In other words, the amount of image charge generated is proportional to the intensity of the image light, which is read out as analog image signals from the column bitlines and converted to digital values to produce digital images (i.e., image data) representing the external scene.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1A illustrates a cross-sectional view of a void formed within a deep trench isolation structure for explaining a problem faced by conventional image sensors or other CMOS devices.

FIG. 1B illustrates a top view of an image sensor having wafer cracks caused by deep trench isolation structures with voids.

FIG. 2A illustrates a top view of an image sensor in accordance with embodiments of the present disclosure.

FIG. 2B is an example cross-section view of a pixel array including a non-visible light pixel adjacent to a visible light pixel, the non-visible light pixel having a cell deep trench isolation structure, in accordance with embodiments of the present disclosure.

FIG. 3A is an example cross-section view of a pixel including two deep trench isolation structures, each having a wide portion and a narrow portion, and a cell deep trench isolation structure, in accordance with embodiments of the present disclosure.

FIG. 3B is an example close-up view of two deep trench isolation structures and a cell deep trench isolation structure, in accordance with embodiments of the present disclosure.

FIG. 4 is an example method of forming a pixel with deep trench isolation structures and a cell deep trench isolation structure, in accordance with embodiments of the present disclosure.

FIG. 5A is an example cross-sectional view of a pixel illustrating depositing a first patterned layer of photoresist onto a semiconductor substrate, in accordance with embodiments of the present disclosure.

FIG. 5B is an example cross-sectional view of a pixel illustrating etching a first wide trench, a second wide trench, and a third wide trench through the first patterned layer of photoresist, in accordance with embodiments of the present disclosure.

FIG. 5C is an example cross-sectional view of a pixel illustrating etching openings through a second patterned layer of photoresist to form a first narrow trench and a second narrow trench, in accordance with embodiments of the present disclosure.

FIG. 5D is an example cross-sectional view of a pixel illustrating removing of at least one patterned layer of photoresist, in accordance with embodiments of the present disclosure.

FIG. 5E is an example cross-sectional view of a pixel illustrating filling the trenches with one or more materials to form a first deep trench isolation structure, a second deep trench isolation structure, and a cell deep trench isolation structure, in accordance with embodiments of the present disclosure.

FIG. 6 is an example cross-sectional view of a pixel illustrating another example of deep trench isolation structures and a cell deep trench isolation structure in accordance with embodiments of the present disclosure.

FIG. 7 is an example cross-sectional view of a pixel illustrating yet another example of deep trench isolation structures and a cell deep trench isolation structure in accordance with embodiments of the present disclosure.

FIG. 8 is a functional block diagram of an imaging system including an image sensor, in accordance with embodiments of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. In addition, common but well-understood elements that are useful or necessary in a commercially feasible embodiment are often not depicted in order to facilitate a less obstructed view of these various embodiments of the present technology.

### DETAILED DESCRIPTION

For applications such as security and automotive applications, it may be preferable that an associated image sensor provides high quality images in the visible light spectrum as well as has improved sensitivity in the infrared (IR) and/or near infrared (NIR) portions of the light spectrum. For instance, IR or NIR sensors may be used to provide improved visibility and imaging in low light and foggy conditions as well as help detect warmer objects in cooler environments.

Various examples directed to an imaging system with pixel cells including deep trench isolation structures and cell deep trench isolation structures that improve near infrared light sensitivity and processing reliability (such as mitigating substrate cracking) are described herein. In the following description, numerous specific details are set forth to provide a thorough understanding of the examples. One skilled in the relevant art will recognize, however, that the techniques described herein can be practiced without one or more of the specific details, or with other methods, components, materials, etc. In other instances, well-known structures, materials, or operations are not shown or described in detail in order to avoid obscuring certain aspects.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

Spatially relative terms, such as “beneath,” “below,” “over,” “under,” “above,” “upper,” “top,” “bottom,” “left,” “right,” “center,” “middle,” and the like, may be used herein for ease of description to describe one element or feature's relationship relative to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” can encompass both an orientation of above and below. The device may be otherwise oriented (rotated ninety degrees or at other orientations) and the spatially relative descriptors used herein are interpreted accordingly. In addition, it will also be understood that when an element is referred to as being “between” two other elements, it can be the only element between the two other elements, or one or more intervening elements may also be present.

It is appreciated that the term “photodiode region” may correspond to a region within the semiconductor substrate that has been doped, for example by ion implantation, to have an opposite charge carrier type (i.e., conductivity type) relative to the majority charge carrier type of the semiconductor substrate such that an outer perimeter of the doped region (e.g., herein referred to as a photodiode region) forms a PN junction or a PIN junction of a photodiode. For example, an N-doped region, formed in a P-type semiconductor substrate (via ion implantation of phosphorus or arsenic or the like), forms a corresponding photodiode region. In some embodiments, a given pixel may further include a pinning region (e.g., a doped region disposed between a side of the semiconductor substrate and the photodiode region having a conductivity type opposite of the photodiode region conductivity type) to form a pinned photodiode. For example, the pinning region may have a P-type conductivity when the photodiode region has an N-type conductivity, and the semiconductor substrate is also has a P-type conductivity.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

As will be discussed, various examples of an imaging system with an array of pixel cells including deep trench isolation (DTI) structures and cell deep trench isolation (CDTI) structures are disclosed, which collectively improve quantum efficiency (QE) performance and light sensitivity in a near infrared (NIR) or infrared (IR) light regime. In various examples, the deep trench isolation (DTI) structured may further provide isolation between adjacent pixel cells to reduce optical/electrical crosstalk. In various examples, the CDTI structures may be included in pixel cells adapted to detect NIR light, IR light, and/or the visible light spectrum as well as one or more of the neighboring pixel cells that are adapted to detect the same or other colors of light such as red light, green light, blue light, etc. As will be shown, in the various examples the pixel cells include a photodiode disposed in a pixel cell region of a semiconductor layer (or semiconductor substrate) and proximate to a second side of the semiconductor layer to generate image charge in response to incident light that is directed through a first side of the semiconductor layer to the photodiode. A CDTI structure is disposed in the pixel cell region of the semiconductor layer along an optical path of the incident light to the photodiode and proximate to a backside of the semiconductor layer. Further, in various examples, DTI structures, including a wide portion and a narrow portion, may be included to avoid formation of voids in DTI structures mitigating issues with substrate cracking. The wide trench of the DTI structure may have a substantially similar trench dimension as the CDTI structure. For example, the depth, width, or both depth and width of the wide trench of the DTI structure may be substantially similar to a corresponding depth and width of the CDTI structure. The narrow portion may have a width smaller than the width of the wide portion. The wide portion may have a uniform width throughout its depth, while the narrow portion may taper or decrease in trench width as it extends towards the second side of the semiconductor substrate. In this manner, the configuration of the DTI structures can prevent voids (e.g., air gaps) from forming in the DTI structures, which can reduce or prevent cracking of the semiconductor substrate.

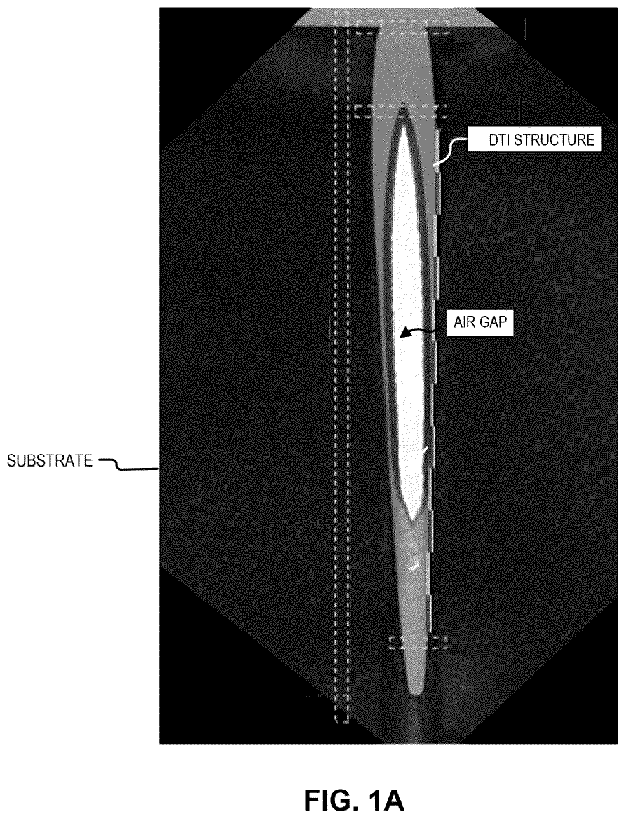

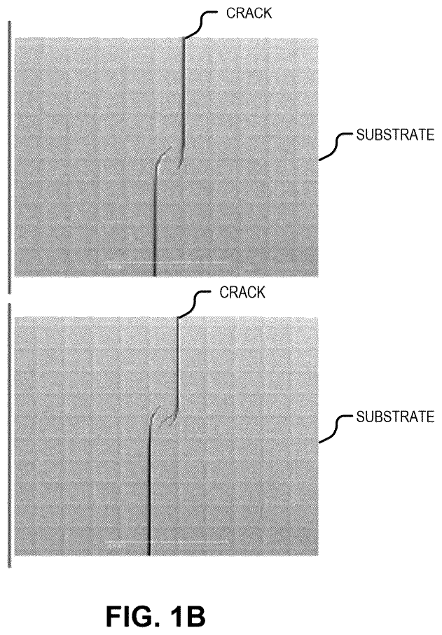

During the formation of DTI structures, voids (e.g., air gaps) within the DTI structure may be formed, as illustrated by FIG. 1A. FIG. 1A is a photograph of a cross section of an air gap inside a deep trench isolation structure. Conventional DTI structures may result in a structure having a narrow opening on the first side of the semiconductor substrate and a wider cavity as the DTI structure extends into the semiconductor substrate towards the second side of the semiconductor substrate after material deposition. Due to a high aspect ratio (e.g., the ration between the depth and the width being greater than 15) of the DTI structure, when the DTI structure is filled with material, an air gap or void may form within it. The material filling the DTI structure may only be able to partially fill the trench and result in void formation.

FIG. 1B is a photograph of example cracks in a substrate or wafer with deep trench isolation structures formed therein. Two wafers are shown from a top-down perspective. As shown, the wafer includes a grid formed by the aforementioned DTI structures illustrated in FIG. 1A. The formation of air gaps or voids in the DTI structures may often lead to cracking of the wafer as stress is accumulated during the fabrication process, as shown in FIG. 1B. Cracks may be formed in each wafer, along the grid formed by the DTI structures. The cracking may worsen when the DTI structures have a high aspect ratio (e.g., greater than 15), such as shown in FIG. 1A.

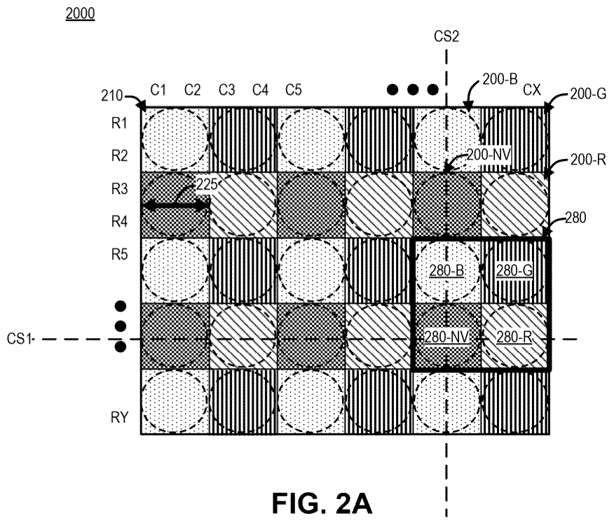

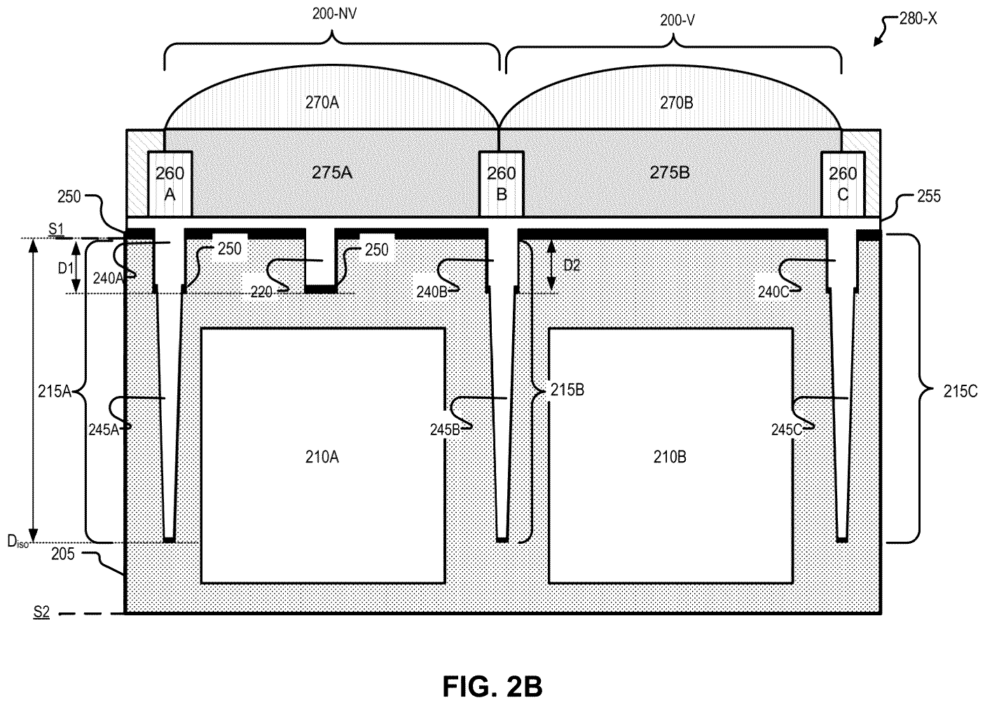

FIG. 2A illustrates a top view of an image sensor 2000, in accordance with embodiments of the present disclosure. As illustrated, image sensor 2000 may be addressed or otherwise described as having an array including a plurality of rows (e.g., R1, R2, R3, . . . , RY) and columns (e.g., C1, C2, C3, . . . , CX). Each element of the array with Y rows and X columns may include a respective photodiode region 210A, 210B (or photodiode) and light filter (as shown in FIG. 2B). It is appreciated that certain elements may be omitted or unlabeled (e.g., plurality of photodiode regions 210, plurality of color filters 275, respective portions of semiconductor substrate 205, and the like illustrated in FIG. 2B) to avoid obscuring certain aspects of the disclosure.

In the illustrated embodiment of FIG. 2A, includes a pixel array formed by an arrangement of a plurality of pixels e.g., pixels 200-B, 200-G, 200-R, 200-NV. The plurality of pixels may include blue color pixels 200-B, green color pixels 200-G, red color pixels 200-R, and non-visible light filters 200-NV (e.g., infrared (IR) light pixels, near-infrared (NIR) light pixels, or other light pixels outside of the visible spectrum of electromagnetic radiation such as 700 nm to 2500 nm) arranged in a pre-determined pattern. It should be understood that blue color pixels 200-B, green color pixels 200-G, and red color pixels 200-R all represent visible color filters (illustrated as 200-V in FIG. 2B) having a color within the visible spectrum of electromagnetic radiation (380 nm to 700 nm). A pixel cell 280 may include groups of four pixels (e.g., pixels 200-B, 200-G, 200-R, 200-NV). In some embodiments, the groups of four color pixels 200 include a first color pixel with a first spectral photoresponse, a second color pixel with a second spectral photoresponse, a third color pixel with a third spectral photoresponse, and a fourth color pixel with a fourth spectral photoresponse, which may be represented by pixel cell 280. The groups of four color pixels may be arranged based on a Bayer pattern. As illustrated in FIG. 2A, the pixel cell 280 is representative of a full-color image pixel with a predetermined arrangement of different filters such that image signals (e.g., electrical signals having a magnitude proportional to intensity of incident light) generated by the underlying photodiodes are collectively representative of the visible spectrum of electromagnetic radiation. As illustrated, pixel cell 280 includes four color pixels, 280-B, 280-G, 280-R, and 280-NV. In some embodiments, pixel cell 280 includes a blue color pixel 280-B, a green color pixel 280-G, a red color pixel 280-R, and a non-visible light pixel 280-NV. Also illustrated are a first cross-section line across the pixel cell 280 CS1 along a first direction (e.g., row direction) and a second cross-section line across the pixel cell 280 CS2 along a second direction perpendicular to the first direction (e.g., column direction).

FIG. 2B is an example cross-section view of a pixel cell 280-X including a non-visible light pixel 200-NV adjacent to a visible light pixel 200-V, the non-visible light pixel 200-NV having a cell deep trench isolation (CDTI) structure 220, in accordance with embodiments of the present disclosure. More specifically, the cross-sectional view of pixel cell 280-X may be a representative view taken along a row or column of image sensor 2000 of FIG. 2A including a non-visible light pixel 200-NV and may be representative of pixel cell 280. In embodiments, pixel cell 280-X may be representative of a cross-section view taken along the first cross section line CS1 or second cross section line CS2 of FIG. 2A. It is appreciated that certain elements may be omitted (e.g., gate electrodes, source/drain regions of transistors, contacts, metal layers, and so on) to avoid obscuring certain aspects of the disclosure. Referring back to FIG. 2B, pixel cell 200 includes a semiconductor substrate 205 (e.g., silicon, silicon germanium alloy, germanium, silicon carbon alloy, an indium gallium arsenide alloy, any other alloys formed of III-V compounds, other semiconductor materials or alloys, combinations thereof, a substrate thereof, a bulk substrate thereof, or a wafer thereof). In some embodiments, the semiconductor substrate 205 has a first side S1 (e.g., a backside or a frontside) and a second side S2 opposite the first side S1. (e.g., a frontside or backside). Pixel cell 200 also includes a plurality of photodiode regions 210 (e.g., 210A, 210B) arranged as a photodiode array, each of the plurality of photodiodes 210 disposed within respective portions of semiconductor substrate 205. In some embodiments individual photodiode regions 210A, 210B included in the plurality of photodiode regions 210 may correspond to doped regions within the respective portions of semiconductor substrate 205 that are collectively responsive to incident light (e.g., the doped regions may form a PN junction that generates electrical or image charge proportional to a magnitude or intensity of the incident light). Portions of the semiconductor substrate 205 disposed between adjacent photodiodes (e.g., region of substrate 205 between photodiode regions 210A and 210B) may be utilized to form additional structures within the semiconductor material (e.g., isolation trenches, floating diffusion, and the like). In the illustrated embodiment, the CDTI structure 220 is included in the non-visible light pixel 200-NV while the color visible pixel 200-V omits a CDTI structure i.e., the color visible pixel 200-V does not have any CDTI structure disposed within its respective photodiode region 210B. It is appreciated that in the illustrated embodiment, a single CDTI structure is included, but in some embodiments, the illustrated CDTI structure may be a portion of a light refractive structure or a part of array of CDTI structure disposed in a given non-visible light pixel 200-NV, or more than one CDTI structures may be included depending on the desire quantum efficiency needed for the non-visible light pixel 200-NV.

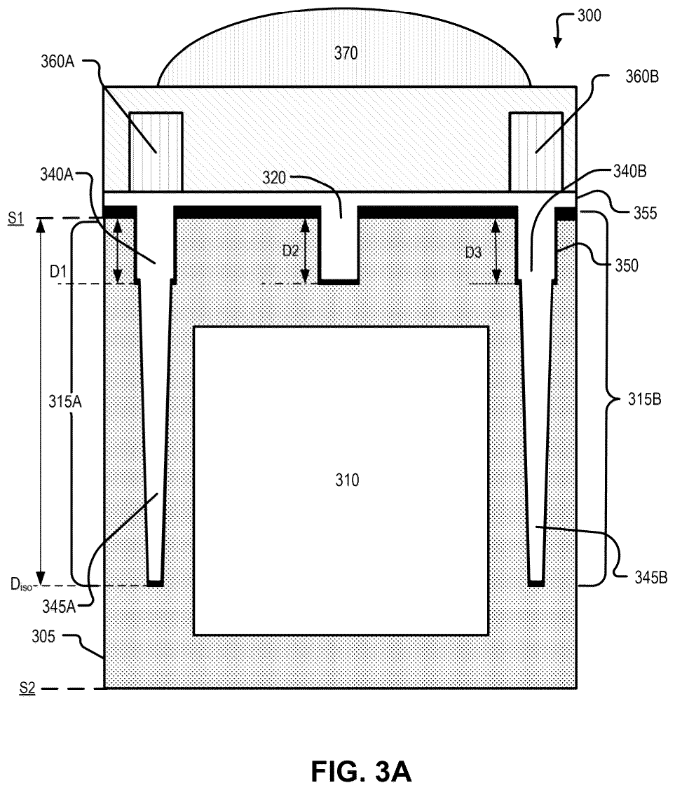

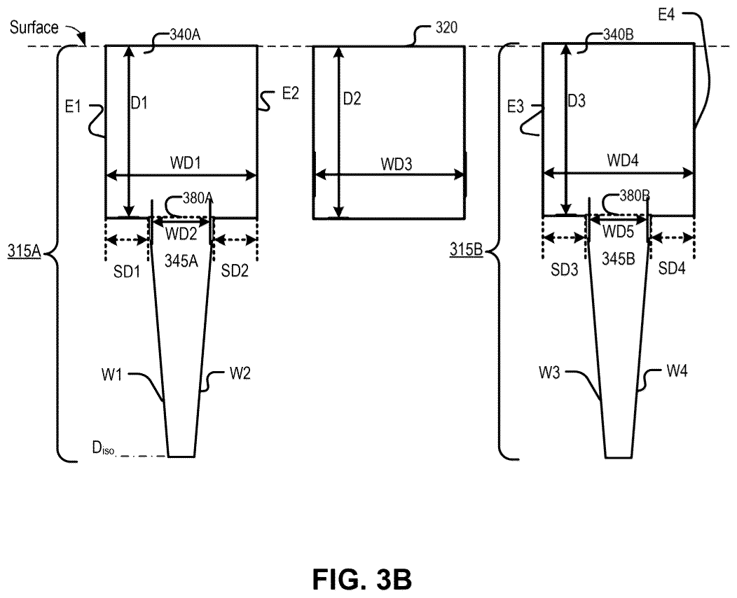

In the illustrated embodiment, a plurality of deep trench isolation (DTI) structures 215 (e.g., 215A, 215B, and 215C) are formed or otherwise disposed between adjacent photodiode regions (e.g., 210A, 210B) include in the plurality of photodiode regions 210 to, for example, reduce the optical or electrical cross-talk between the adjacent photodiode regions. In some embodiments, the plurality of DTI structures 215 collectively forms a deep trench isolation grid extending from the first side S1 of semiconductor substrate 205 towards the second side S2 to laterally surround and isolate (e.g., optically and/or electrically) adjacent photodiodes regions (e.g., photodiode regions 210A, 210B) from one another in the color filter array. Each of the plurality of DTI structures 215 are configured to extend from the first side S1 into the semiconductor substrate 205 towards the second side S2. As described in further detail herein, the plurality of DTI structures 215 each include a first or wide portion 240 (e.g., 240A, 240B, and 240C) and a second or narrow portion 245 (e.g., 245A, 245B, 245C). In some embodiments, the wide portion 240 has a first width, (see, e.g., WD1 of FIG. 3B) and the narrow portion 245 has a second width (see, e.g., WD2 of FIG. 3B). In some embodiments, the first width is larger than the second width, for example, along a row or column direction of FIG. 2A depending on the orientation of the cross-sectional view of FIG. 2B. In some embodiments, the wide portion 240 of each of the plurality of DTI structures 215 extends into the semiconductor substrate 205 towards the second side 205 to a first depth (see D1 of FIGS. 2B and 3B) with respect to the first side S1 in a depth-wise direction. In the illustrated embodiments, each of narrow portions 245 (e.g., 245A, 245B, 245C) may extend from the respective wide portion 240 (e.g., 240A, 240B, and 240C) to an isolation depth (see Dᵢₛₒ of FIGS. 2B and 3B) in the depth-wise direction that is greater than the first depth with respect to the first side S1. The wide portion 240 (e.g., 240A, 240B, and 240C) and the respective narrow portions 245 (e.g., 245A, 245B, 245C) may be structurally integrated or otherwise connected. The wide portions 240 and their respective narrow portions 245 collectively provides isolation between adjacent photodiode regions.

As illustrated in FIG. 2B, the non-visible light pixel 200-NV further includes a cell deep trench isolation (CDTI) structure 220. The CDTI structure 220 extends into the semiconductor substrate 205 from the first side S1 towards the second side S2. The CDTI structure 220 may be disposed in a center region or a respective photodiode, e.g., photodiode region 201. In one embodiment, the CDTI structure 220 is aligned to a centerline of the photodiode region 210A that is normal to a surface of the first side S1 (e.g., centered with the photodiode region 210A). In some embodiments, the CDTI structure 220 may be offset from the centerline of the photodiode region 210A that is normal to a surface of the first side S1 depending on position of the respective non-visible light pixel 200-NV within the pixel array. The CDTI structure 220 extends into the semiconductor substrate 205 to a second depth (see, e.g., D2 in FIGS. 2B and 3B) with respect to the first side S1 and the CDTI structure 220 has a third width (see, e.g., WD3 in FIG. 3B). The second depth (see, e.g., D2 in FIGS. 2B and 3B) is less than the isolation depth Dᵢₛₒ with respect to the first side S1.

In the illustrated embodiment, the pixel cell 280-X includes a buffer oxide layer 255 formed over the first side S1 of the substrate 205. The plurality of DTI structures 215, the CDTI structure 220, or both may include a lining layer 250 lining surfaces of their respective trench structure separating a fill material (e.g., one or more DTI fill materials or CDTI fill materials) from the semiconductor substrate 205. In operation, the CDTI structure 220 may improve quantum efficiency (QE) performance, near infrared (NIR) light sensitivity, and/or reduce cross-talk. In some embodiments, the CDTI structure 220 is formed with a low k material, an oxide material, or other suitable dielectric material. In some embodiments, the lining layer 250 may correspond to or otherwise include an oxide-based material, a high-k material dielectric material having a dielectric constant greater than silicon dioxide (e.g., dielectric constant greater than 3.9), a high-k material dielectric material having negative charges, or a combination thereof. The lining layer 250 may be a single layer or a stack of material layers with appropriate thickness to provide surface passivation and anti-reflection functionality. The plurality of DTI structures 215 may include one or more DTI fill materials (e.g., silicon dioxide polysilicon, metal material, or combinations thereof) to provide electric and/or optical isolation between adjacent photodiode regions 210A, 210B. In the depicted example, a metal grid 260, including sections 260A, 260B, 260C, is formed with sections disposed between adjacent color filters (e.g., color filters 275A and 275B) included in a plurality of color filters 275 of the color filter array layer separating adjacent color filters. The metal grid 260 may include a plurality of sections such as 260A, 260B, 260C that collectively form a plurality of apertures optically aligned with respective photodiode regions such as photodiode regions 210A, 210B. A microlens layer including a plurality of microlenses 270 is formed over the color filter array layer.

In some embodiments, pixel cell 280-X includes a plurality of microlenses 270 arranged as a microlens array optically aligned with the color filter array (e.g., formed by plurality of color filters 275) and the photodiode array (e.g., formed by plurality of photodiode regions 210). Each of the microlenses may be formed of a polymer (e.g., polymethylmethacrylate, polydimethylsiloxane, etc.) or other material and be shaped to have optical power for converging, diverging, or otherwise directing light incident upon the plurality of microlenses 270 (e.g., 270A) through a corresponding optically aligned one (e.g., color filter 275A) of the plurality of color filters 275 to a photodiode region (e.g., 210A) included in the plurality of photodiodes 210. In some embodiments there is a 1-to-1 ratio between the number of filters included in the plurality of color filters 275 and the number of microlenses included in the plurality of microlenses 270.

In the illustrated embodiment, the plurality of color filters 275 may be arranged as a color filter array optically aligned with the photodiode array formed by the plurality of photodiode regions 210. The plurality of color filters 275 may include N filters (e.g., color filters 275A, . . . 275N) that each have a specific spectral photoresponse to filter incident light propagating through an individual one of the plurality of color filters 275 to an individual photodiode region 210. For example, non-visible filter 275A is optically aligned with photodiode 210A.

The pixel cell 280-X may further include a visible color pixel 200-V. Visible color pixel 200-V includes a color filter 275B. It should be understood that visible color pixel 200-V may have any suitable color filter with a color within the visible spectrum of electromagnetic radiation. It is appreciated that the plurality of color filters 275 is not limited to a single spectral photoresponse and that other types of filters may be included in pixel cell 200 with corresponding spectral photoresponse substantially equivalent to any one of, or a combination of, red, green, blue, panchromatic (i.e., clear or white), yellow, cyan, non-visible (i.e., infrared) and/or magenta colors. In some embodiments, the plurality of color filters 275 may consequently be utilized to generate image signals representative of the incident light within at least the visible spectrum and the non-visible spectrum to generate an image representative of an external scene. It should be understood that visible color pixel 200-V could be any of the color pixels 200-B, 200-G, 200-R illustrated in FIG. 2A.

As shown in the depicted example, each microlens 270A and 270B and each color filter 275A and 275B is disposed over and aligned with a respective photodiode region 210A, 210B of the respective pixel 200-NV, 200-V. As such, the optical path along which incident light is directed passes through a respective microlens 270A, 270B, color filter 275, buffer oxide layer 255, first side S1, and through the semiconductor substrate 205 to a photodiode region 210 as shown. NIR/IR light may be absorbed deeper in the semiconductor substrate 205 than visible light. Accordingly, in the non-visible light pixel 200-NV, the CDTI structure 220 may provide scattering to increase the optical light absorption of non-visible light as the incident light directed to the respective photodiode region via reflection and/or refraction to improve sensitivity performance of the respective non-visible light pixel 200-NV.

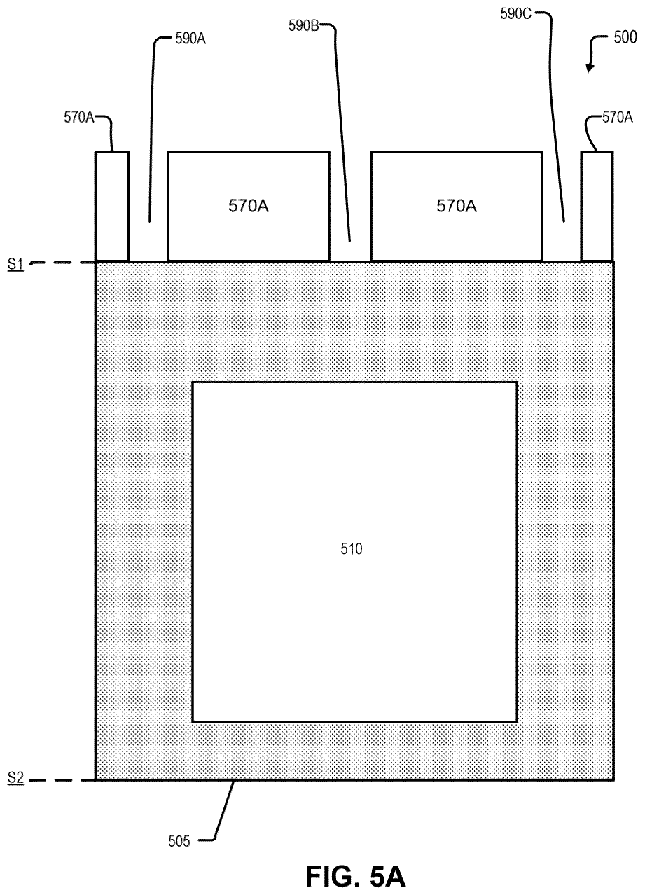

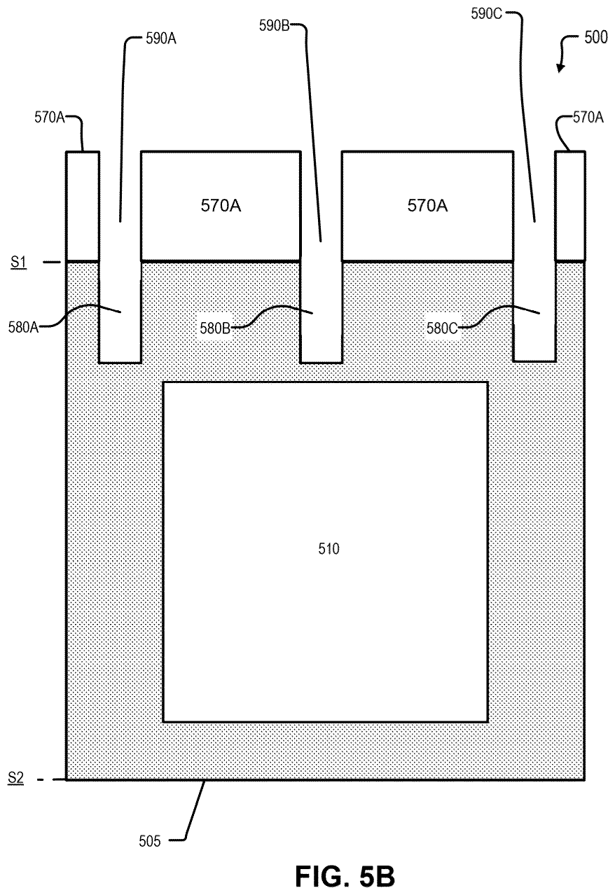

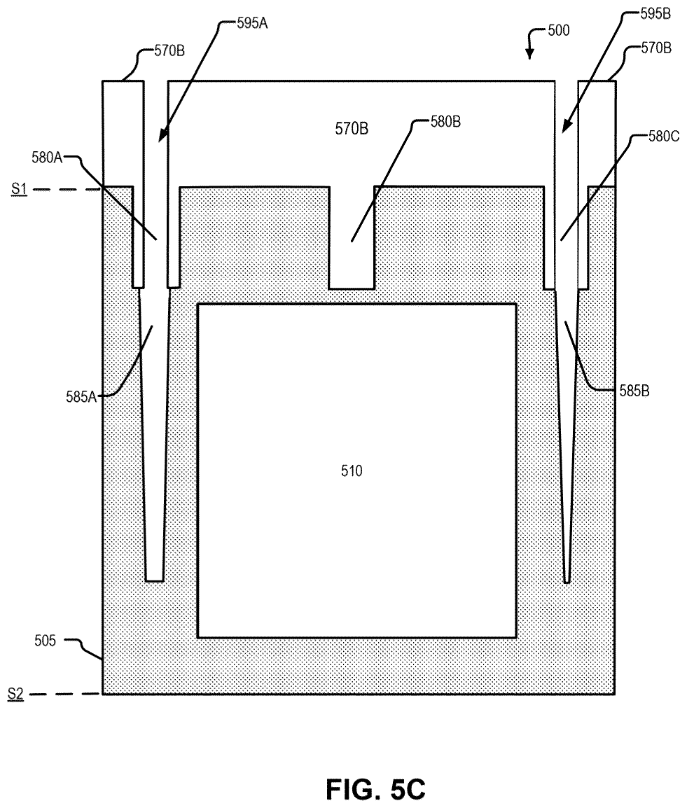

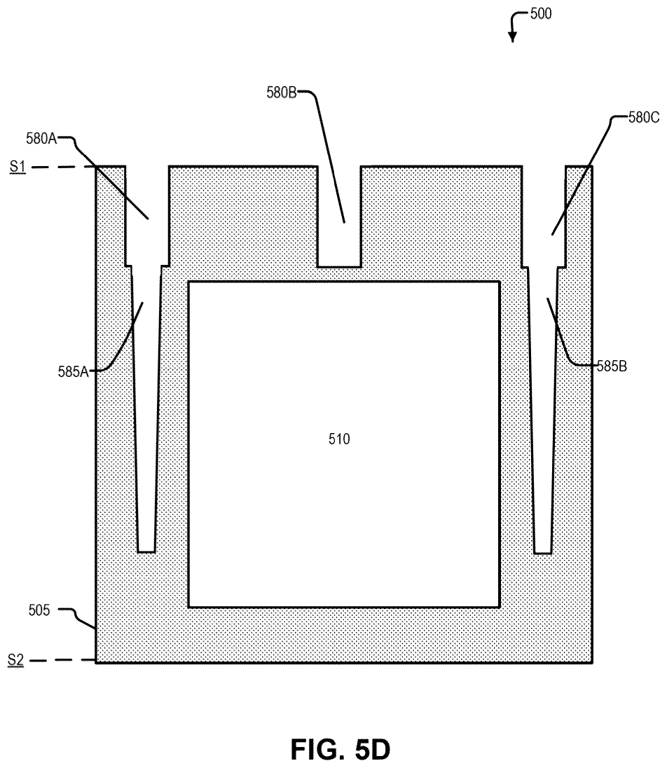

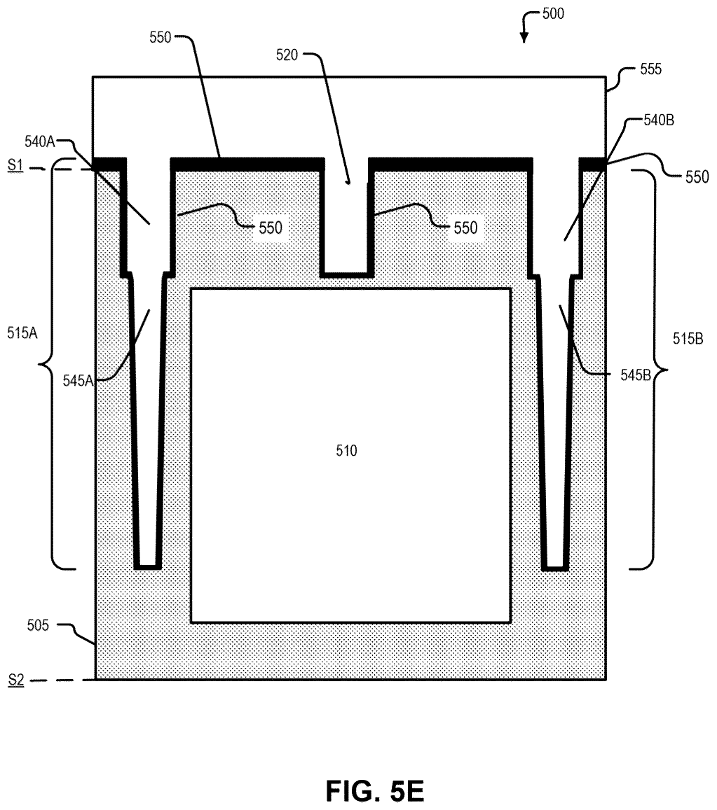

It is appreciated that aspects of pixel cell 280-X may be fabricated by semiconductor device processing and microfabrication techniques known by one of ordinary skill in the art. In one embodiment, fabrication of pixel cell 280-X may include providing a semiconductor substrate or material 205 (e.g., a silicon wafer having a first side S1 and a second side S2), forming a mask or template (e.g., out of cured photo resist) on the front side of the semiconductor substrate 205 via photolithography to provide a plurality of exposed regions of the front side of semiconductor substrate 205, doping (e.g., via ion implantation, chemical vapor deposition, physical vapor deposition, and the like) the exposed portions of the semiconductor substrate 205 to form the plurality of photodiodes 210, removing the mask or template (e.g., by dissolving the cured photoresist with a solvent), and planarizing (e.g., via chemical mechanical planarization or polishing) the front side of semiconductor substrate 205. In the same or another embodiment, photolithography may be similarly used to form the plurality of color filters 275 (e.g., cured pigmented polymers having a desired spectral photoresponse) and the plurality of microlenses 270 (e.g., polymer based microlenses having a target shape and size formed from a master mold or template). It is appreciated that the described techniques are merely demonstrative and not exhaustive and that other techniques may be utilized to fabricate one or more components of pixel cell 280-X. Methods of fabricating other aspects of pixel cell 280-X (e.g., the plurality of DTI structures, the CDTI structure, filling the plurality of DTI structures, and the like) will be described elsewhere herein (i.e., FIGS. 5A-5E).

FIG. 3A is an example cross-sectional view of a pixel 300 including a two deep trench isolation (DTI) structures 315A, 315B, each having a wide portion 340 and a narrow portion 345, and a cell deep trench isolation (CDTI) structure 220, in accordance with embodiments of the present disclosure. Pixel 300 is substantially similar to non-visible light pixel 200-NV illustrated in FIGS. 2A-2B, and includes a semiconductor substrate 305 (e.g., silicon, germanium alloy, germanium, silicon carbide alloy, an indium gallium arsenide alloy, any other alloys formed of III-V compounds, other semiconductor materials or alloys, combinations thereof, a substrate thereof, a bulk substrate thereof, or a wafer thereof), a photodiode region 310, a microlens 370, and a metal grid 360, including portions 360A and 360B. A light filter (e.g., color filter 275 in FIG. 2B) is omitted for clarity. In other words, pixel 300 is one possible implementation of a pixel including the plurality of pixels 280-R, 280-G, 280-B, and 280-NV illustrated in FIGS. 2A-2B. In embodiments, pixel 300 may be representative of a cross-section view of pixel cell 280 taken along the first cross-section line CS1 or the second cross-section line CS2 of FIG. 2A. As illustrated in FIG. 3A, the pixel 300 includes a plurality of DTI structures 315A, 315B, each having a wide portion 340 (e.g., 340A, 340B) and a narrow portion 345 (e.g., 345A, 345B). In some embodiments, the plurality of DTI structures 315 laterally surround and isolate the photodiode region 310 from neighboring photodiode regions. In some embodiments, the plurality of DTI structures 315 include a lining layer 350 and a buffer oxide layer 355. Lining layer 350 and buffer oxide layer 355 may be examples of aforementioned lining layer 250 and buffer oxide layer 255, respectively.

In some embodiments, the pixel 300, includes semiconductor substrate 305 including a first side S1 (e.g., a backside or a frontside) and a second side S2 (e.g., a frontside or a backside) opposite the first side. The pixel 300 further includes a first DTI structure 315A and a second DTI structure 315B, each extending from the first side S1 of the semiconductor substrate 305 towards the second side S1, the first DTI structure 315A including a wide portion 340A and a narrow portion 345A extending from the wide portion 340A such that the narrow portion 345A is disposed between the wide portion 345A and the second side S2 of the semiconductor substrate 305.

FIG. 3B is an example close-up view of two deep trench isolation (DTI) structures 315A and 315B, and a cell deep trench isolation (CDTI) structure 320, in accordance with embodiments of the present disclosure. It should be understood that the first DTI structure 315A may be representative of any of the DTI structures described in embodiments of the disclosure (e.g., 215A, 215B, 315B, or other DTI structures positioned to isolate one or more photodiode regions). It should also be understood that FIG. 3B is not necessarily to scale. The first DTI structure 315A includes a wide portion 340A and a narrow portion 345A. The wide portion 340A extends into the semiconductor substrate (not pictured in FIG. 3B) to a first depth D1 with respect to a surface of the semiconductor substrate e.g., the first side S1 surface of the semiconductor substrate 305. The wide portion 340A also has a first width WD1. The narrow portion 345A extends from the first depth to an isolation depth Dᵢₛₒ that is greater than the first depth with respect to the surface of the semiconductor substrate, e.g., the first side S1 surface of the semiconductor substrate 305. The wide portion 340A and the respective narrow portions 345A may be structurally integrated or otherwise connected. The narrow portion 345A has a second width WD2. In some embodiments, an aspect ratio corresponding to the first width WD1 with respect to a total depth the first DTI structure 315A extends into the semiconductor substrate from the first side S1 is at least 15. The total depth of the first DTI structure is the depth that the narrow portion extends into the semiconductor substrate from the surface of the semiconductor substrate e.g., the first side S1 surface of the semiconductor substrate 306, which is denoted by the isolation depth Dᵢₛₒ. Similarly, the second DTI structure 315B include a wide portion 340B and a narrow portion 345B. The wide portion 340B extends into the semiconductor substrate (not pictured in FIG. 3B) to a third depth D3 with respect to a surface of the semiconductor substrate 305. The narrow portion 345B extends from an end of the wide portion 340B toward the second side S2 to the isolation depth Dᵢₛₒ that is greater than the third depth with respect to the surface of the semiconductor substrate, e.g., the first side S1 surface of the semiconductor substrate 305. The wide portion 340B and the respective narrow portions 345B may be structurally integrated or otherwise connected. The CDTI structure 320 extends to a second depth D2 and has a third width WD3 . . . . In some embodiments, the CDTI structure 320 may have substantially the same trench profile as at least one of the wide portion 340A of the first DTI structure 315A and/or the wide portion 340B of the first DTI structure 315B. In some embodiments, the first width WD1 of the wide portion 345A is substantially equal (e.g., within 10% or otherwise based on the variance attributed to the fabrication process associated with a respective technology node) to the third width WD3 of the CDTI structure 320. Similarly, in the same and other embodiments, the first depth D1 and the second depth D2 are substantially equal (e.g., within 10% or otherwise based on the variance attributed to the fabrication process associated with a respective technology node).

As shown in the illustrated embodiment, the first width WD1 is substantially uniform (e.g., within 10% or otherwise based on the variance attributed to the fabrication process associated with a respective technology node) throughout the wide portion 345A, while the second width WD2 tapers towards the second side S2 of the semiconductor substrate (not pictured in FIG. 3B). That is, the first DTI structure 315A may have a substantially uniform width (e.g., first width WD1) until the first depth D1, and a decreasing width from the first depth D1 toward the isolation depth Dᵢₛₒ that varies with depth along a depth-wise direction. In some embodiments, the first width WD1 is between approximately two to approximately six times greater than the second width WD2. In such embodiments, the ratio between the first width and the second width allows for the first DTI structure 315A to be filled without air gaps or voids. In this way, cracking of the substrate (such as shown in FIG. 1B) may be avoided. As shown in the illustrated embodiment, the fourth width WD4 is substantially uniform throughout the wide portion 345B, while the fifth width WD5 tapers towards the second side S2 of the semiconductor substrate (not pictured in FIG. 3B). That is, the second DTI structure 315B may have a substantially uniform width (e.g., fourth width WD4) until the third depth D3, and a decreasing width from the third depth D3 toward the isolation depth Dᵢₛₒ that varies with depth along a depth wise direction. It is appreciated that DTI 315B may include the same or similar features as DTI 315A. In some embodiments, the third depth may be substantially the same as the first depth D1 (e.g., within 10% or otherwise based on the variance attributed to the fabrication process associated with a respective technology node). Similarly, the fourth width WD4 may be substantially the same as the fourth depth D4.

As illustrated in FIG. 3B, the wide portion 340A includes a first edge E1 and a second edge E2 opposite the first edge E1. The narrow portion 345 includes a first wall W1 and a second wall W2 opposite the first wall W1. An interface 380A between the wide portion 340A and the narrow portion 345A defines a first separation distance SD1 between the first edge E1 and the first wall W1 and a second separation distance SD2 between the second edge E2 and the second wall W2. A combination of the first separation distance SD1, the second separation distance SD2, and the second width WD2 of the narrow portion 345A is substantially equal (e.g., within 10% or otherwise based on the fabrication process) to the first width WD1 of the wide portion 340A. In some embodiments, such as that illustrated in FIG. 3B, the narrow portion 345A is centrally aligned with the wide portion 340A such that the first separation distance SD1 is substantially equal to the second separation distance SD2. In some embodiments, the narrow portion 345A is offset from the wide portion 340A such that the first separation distance SD1 is different from the second separation distance SD2. In some embodiments, the third width WD3 of the CDTI structure 320 is greater than a combined width of the first separation distance SD1 and the second separation distance SD2. As defined herein, the term “substantially” is used to indicate that a value includes the inherent variation of error for the quantifying device, the method being employed to determine the value, or the natural variation due to fabrication. For example, but not by way of limitation, when the term “substantially” is used the designation value may vary by plus or minus 10%.

In some embodiments, the second DTI structure 315B includes a second wide portion 340B and a second narrow portion 345B extending from the second wide portion 340B such that the second narrow portion 345B is disposed between the second wide portion 340B and the second side S2 of the semiconductor substrate 305. In some embodiments, a width of the second wide portion 340B is greater than a width of the second narrow portion 345B. The second wide portion 345B extends to a third depth D3 substantially equal to the first depth and the second depth (D1 and D2 of FIG. 3B, respectively). It is appreciated that second DTI structure 315B may have a similar or even identical structure to the DTI structure 315A in FIG. 3B. In some embodiments, the second wide portion 340B includes a third edge E3 and a fourth edge E4 opposite the third edge E3, and the second narrow portion 345B includes a third wall W3 and a fourth wall W4 opposite the third wall W3. Accordingly, an interface 380B between the second wide portion 340B and the second narrow portion 345B defines a third separation distance SD3 between the third edge E3 and the third wall W3 and a fourth separation distance SD4 between the fourth edge E4 and the fourth wall W4. In some embodiments, the first separation distance SD1 is greater than the second separation distance SD2, and the third separation distance SD3 is greater than the fourth separation distance SD4. In some embodiments, the second narrow portion 345B is offset from the second wide portion 340B such that the third separation distance SD3 is different from the fourth separation distance SD4. In some embodiments, the first narrow portion 345A and the second narrow portion 340B are offset from the first wide portion 340A and the second wide portion 340B, respectively, by a same distance, so that the first separation distance SD1 and the third separation distance SD3 are substantially equal, and the second separation distance SD2 and the fourth separation distance SD4 are substantially equal.

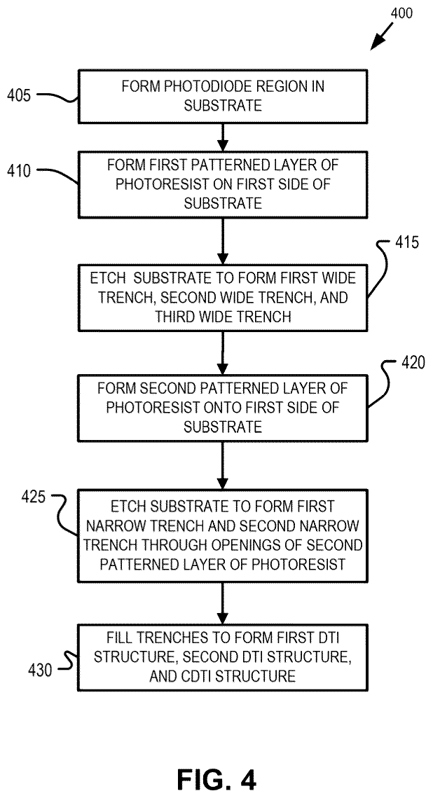

FIG. 4 is an example method 400 of forming a pixel with deep trench isolation (DTI) structures and a cell deep trench isolation (CDTI) structure, in accordance with embodiments of the present disclosure. The method 400 is described with reference to FIGS. 5A-5E. It is appreciated that the order in which some of the process blocks appear in method 400 should not be deemed limiting. Rather, one of ordinary skill in the art having the benefit of the present disclosure will understand that some of the process blocks may be executed in a variety of orders not illustrated, or even in parallel. Method 400 is one possible implementation for forming an image sensor having one or more components (e.g., pixel, pixel cell, DTI structure, CDTI structure, and/or other components) illustrated in FIGS. 2A-3B.

FIG. 5A is an example cross-sectional view of a pixel 500 illustrating depositing a first patterned layer of photoresist 570A onto a semiconductor substrate 505, in accordance with embodiments of the present disclosure. In some embodiments, pixel 500 may be representative of a cross-section view taken along the first cross-section line CS1 or the second cross-section line CS2 of FIG. 2A. The semiconductor substrate 505 may have a first side S1 (e.g., a front side or a backside) and a second side S2 (e.g., a front side or a back side). The semiconductor substrate 505 may also include a photodiode region 510. Returning to FIG. 4, method 400 includes process block 405, where a photodiode region 510 disposed inside of a semiconductor substrate 505 is formed. The semiconductor substrate 505 has a first side S1 and a second side S2 opposite the first side S1. In some embodiments, the first side S1 is a back side of the semiconductor substrate 505, and the second side S2 is a front side. In some embodiments, the first side S1 is an illuminated side of the semiconductor substrate 505, and the second side S2 is a non-illuminated side of the semiconductor substrate 505. In some embodiments, the photodiode region 510 may be formed by implanting the semiconductor substrate 505 from second side S2 with suitable N-type dopants, e.g., arsenic (As) or phosphorus (P) or suitable P-type dopants, e.g., boron (B) at one or more suitable implant energies to achieve a target doping profile.

In block 410, a first patterned layer of photoresist 570A is formed on the first side S1 of the semiconductor substrate 505. In some embodiments, the first patterned layer of photoresist 570A may be deposited onto the first side S1. In some embodiments, the first patterned layer of photoresist 570A includes one or more openings 590A, 590B, and 590C. In some embodiments, the semiconductor substrate 505 may be etched and constituent materials for forming DTI and CDTI structures may be deposited via the openings 590A, 590B, and 590C. In some embodiments, opening 590B is a central opening. In such embodiments, opening 590B is centrally aligned with the underlying photodiode 540.

FIG. 5B is an example cross-sectional view of a pixel 500 illustrating etching the semiconductor substrate 505 to form a first wide trench 580A, a second wide trench 580B, and a third wide trench 580C through the first patterned layer of photoresist 570A, in accordance with embodiments of the present disclosure. In some embodiments, the wide trenches 580 extend from the first side S1 of the semiconductor substrate 505 towards the second side S2. Returning to FIG. 4, in block 415, wide trenches 580 (e.g., a first wide trench 580A, a second wide trench 580B, and a third wide trench 580C) are formed by etching the semiconductor substrate 505 through openings 590A, 590B, and 590C of the first patterned layer of photoresist 570A removing corresponding substrate material from the semiconductor substrate 505. In some embodiments, the semiconductor substrate 505 is dry etched, wet etched, or a combination of dry and wet etched to form wide trenches 580. In some embodiments, a depth, a width, or both a depth and width of the wide trenches 580 are substantially equivalent. In some embodiments, the second wide trench 580B is disposed between the first wide trench 580A and the third wide trench 580C. In some embodiments, the second wide trench 580B is disposed over the photodiode region 510. In some embodiments, the first patterned layer of photoresist 570A is removed after the first, second, and third wide trenches 580 have been formed. In some embodiments, the second patterned layer of photoresist (570B in FIG. 5C) is formed over the top of the first patterned layer of photoresist 570A. In other, or the same embodiments, both layers of photoresist 570 are removed after narrow trenches (585 in FIG. 5C) are formed.

FIG. 5C is an example cross-sectional view of a pixel 500 illustrating etching through openings 595 (e.g., 595A and 595B) of a second patterned layer of photoresist 570B to form a first narrow trench 585A and a second narrow trench 585B, in accordance with embodiments of the present disclosure. Returning to FIG. 4, in block 420, a second patterned layer of photoresist 570B is formed onto the first side S1 of the semiconductor substrate 505. In some embodiments, the second patterned layer of photoresist 570B may be deposited onto the first side S1. In some embodiments, the second patterned layer of photoresist 570B completely fills the second wide trench 580B, but only partially fills the first wide trench 580A and the third wide trench 580C. That is, the second patterned layer of photoresist 570B may be deposited to completely cover the second wide trench 580B but only cover part of the first wide trench 580A and the third wide trench 580C with openings for corresponding narrow trench formation.

In block 425, the semiconductor substrate 505 is etched to form a first narrow trench 585A and a second narrow trench 585B through openings 595 of the second patterned layer of photoresist 570B. In some embodiments, the openings 595 of the second patterned layer of photoresist 570B respectively overlap with the first wide trench 580A and the third wide trench 580C such that the first narrow trench 585A extends from the first wide trench 580A and the second narrow trench 585B extends from the third wide trench 580C. In some embodiments, the narrow trenches 585 are centrally aligned with the first and third wide trenches 580A, 580C such that a first separation distance (such as SD1 in FIG. 3B) is substantially equal to a second separation distance (such as SD2 in FIG. 3B) for each narrow trench 585. In some embodiments, the first width trench 580A and the first narrow trench 585A are structurally integrated or otherwise connected, and the third wide trench 582C0 and the third narrow trench 585B are structurally integrated or otherwise connected. In some embodiments, the narrow trenches 585 are offset from the wide trenches 540 such that the first separation distance is different from the second separation distance.

FIG. 5D is an example cross-sectional view of a pixel 500 illustrating removing of at least one patterned layer of photoresist 570, in accordance with embodiments of the present disclosure. As described herein, in some embodiments, both the first patterned layer of photoresist 570A and the second patterned layer of photoresist 570B are removed.

FIG. 5E is an example cross-sectional view of a pixel 500 illustrating depositing one or more materials 550, 555 into the trenches 580, 585 to form a first deep trench isolation (DTI) structure 515A, a second DTI structure 515B, and a cell deep trench isolation (CDTI) structure 520, in accordance with embodiments of the present disclosure. In some embodiments, lining material 550 is deposited to form a lining layer lining the inner trench surfaces of trenches 580, 585 and first side S1 surface. In some embodiments, the lining material 550 is deposited in a manner such that the formed lining layer continuously lines the inner trench surfaces of trenches 580A, 580B, 580C and first side S1 surface. The lining layer may be an example of lining layer 250, 350. Returning to FIG. 4, in block 430, the wide trenches 580 (e.g., 580A, 580B, 580C) and narrow trenches 585 (e.g., 585A, 585B, 585C) are simultaneously filled with a fill material 555 to form a first DTI structure 515A, a second DTI structure 515B, and a CDTI structure 520, for example by a deposition technique such as chemical vapor deposition, atomic layer deposition, physical vapor deposition, thermal evaporation, magnetron sputtering, or the like. In some embodiments, the first wide trench 580A and the first narrow trench 585A are filled to form the first DTI structure 515A having a first wide portion 540A and a first narrow portion 545A. The second wide trench 580B is filled with fill material to form the CDTI structure 520. Similarly, the third wide trench 580C and the second narrow trench 585B are filled to form the second DTI structure 515B, having a second wide portion 540B and a second narrow portion 545B. In some embodiments, a lining material 550 is deposited to form a lining layer lining the inner trench surfaces of trenches 580, 585 In some embodiments, the lining material 550 may be deposited to form a lining layer on a first side S1 of the semiconductor substrate 505 and into the trench structure of each of the plurality of DTI structures 515 and the CDTI structure 520. The lining material 550 may be deposited in a manner that a thickness of a portion of the lining layer formed on first side S1 is thicker than a thickness of portions lining the inner trench surfaces of trenches 580, 585. The lining material 550 may include high-k material or dielectric material having a dielectric constant greater than 3.9. In some embodiments, the lining material 550 coats the walls of the wide trenches 580 and narrow trenches 585. In some embodiments, the lining material 550 is deposited in a manner such that the formed lining layer continuously lines the inner trench surfaces of wide trenches 580A, 580B, 580C, narrow trenches 585A, 585B, and the first side S1 surface (e.g., portions of first side S1 surface between wide trenches 580A, 580B, 580C). The lining layer may be an example of lining layer 250, 350. In some embodiments, the wide trenches 580 and narrow trenches 585 are later filled with one or more DTI fill materials 555 e.g., silicon dioxide, low-n material, polysilicon, metal material, or combinations thereof. The DTI fill material deposited into the wide trenches 580 (including wide trenches 580A, 580B, 580C) and narrow trenches 585 (including narrow trenches 585A, 585B) may be on and surrounded by the lining layer formed of the lining material 550.

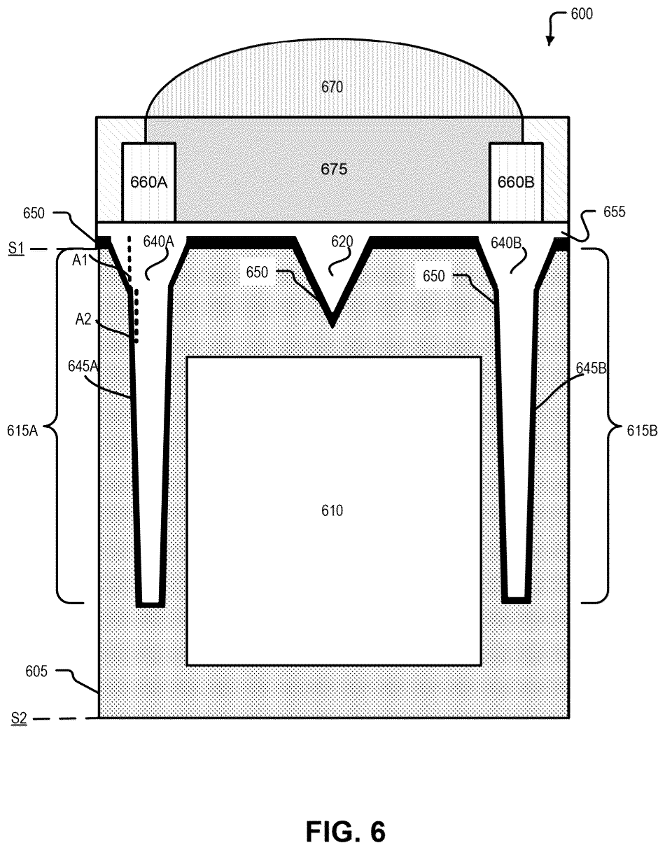

FIG. 6 is an example cross-sectional view of a pixel 600 illustrating another example of deep trench isolation (DTI) structures 615 and a cell deep trench isolation (CDTI) structure 620 in accordance with embodiments of the present disclosure. Pixel 600 is substantially similar to non-visible light pixel 200-NV illustrated in FIGS. 2A-2B and includes the same or similar features including a semiconductor substrate 605 having a first side S1 and a second side S2, a photodiode region 610, DTI structures 615 (e.g., 615A and 615B), CDTI structure 620, a metal grid 660A and 660B, a filter 675, and a microlens 670. The cross-sectional view of pixel 600 may be a representative view taken along a row or column of image sensor 2000 of FIG. 2A, including a non-visible light pixel 600. In some embodiments, pixel 600 may be representative of a cross-section view taken along the first cross-section line CS1 or the second cross-section line CS2 of FIG. 2A. In some embodiments, the plurality of DTI structures 615 include a lining layer 650 and a buffer oxide layer 655.

In some embodiments, the wide portions 640 of the plurality of DTI structures 615 (e.g., 615A and 615B) and the CDTI structure 620 may have a triangular shaped cross section. In some embodiments, the wide portions 640 (e.g., 640A and 640B) of the plurality of DTI structures 615 and the CDTI structure 620 are formed by wet etching the semiconductor substrate 605. By forming the plurality of DTI structures 615 with wet-etching, the plurality of DTI structures can be fabricated at a lower cost. Further, with wet-etching, less damage may be made to the crystal lattice structure of the semiconductor substrate 605 (e.g., silicon) providing smoother trench surfaces, which may have an advantage of mitigating the issue of dark current.

In some embodiments, the wide portion 640 gets thinner as it extends towards the second side S2 of the semiconductor substrate 605. In some embodiments, such as that illustrated in FIG. 6, a first width of the wide portion 640 tapers to a second width of the narrow portion 645 (e.g., 645A or 645B) at a first taper angle A1. It should be understood that first taper angle A1 is the rate at which the width of the wide portion 640 reduces as the wide portion 640 extends towards the second side S2 of the semiconductor substrate 605. The second width tapers towards the second side S2 of the semiconductor substrate 605 throughout the narrow portion 645 at a second taper angle A2. As the narrow portion 645 extends towards the second side S2 of the semiconductor substrate 605, the width of the narrow portion 645 becomes narrower. In some embodiments, the first taper angle A1 is greater than the second taper angle A2. In other words, the degree of taper for the wide portions 640 may be greater than the degree of taper for the narrow portions 645.

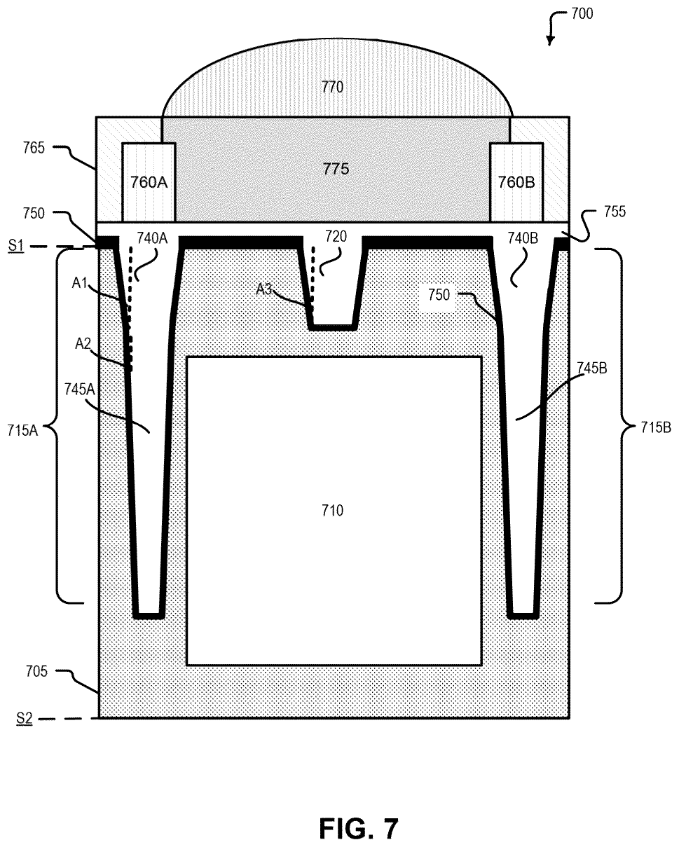

FIG. 7 is an example cross-sectional view of a pixel 700 illustrating yet another example of deep trench isolation (DTI) structures 715 and a cell deep trench isolation (CDTI) structure 720 in accordance with embodiments of the present disclosure. Pixel 700 is substantially similar to non-visible light pixel 200-NV illustrated in FIGS. 2A-2B and includes a semiconductor substrate 705 having a first side S1 and a second side S2, a photodiode region 710, a plurality of DTI structures 715 (e.g., 715A and 715B), a filter 775, a metal grid 760A and 760B, and a microlens 770. In some embodiments, the plurality of DTI structures 715 include a lining layer 750 and a buffer oxide layer 755. The cross-sectional view of pixel 600 may be a representative view taken along a row or column of image sensor 2000 of FIG. 2A, including a non-visible light pixel 700. In some embodiments, pixel 700 may be representative of a cross-section view taken along the first cross-section line CS1 or the second cross-section line CS2 of FIG. 2A.

In some embodiments, the wide portions 740 (e.g., 740A and 740B) of the plurality of DTI structures 715 (e.g., 715A and 715B) and the CDTI structure 720 are trapezoidal. In some embodiments, the plurality of DTI structures further includes a narrow portion 745 (e.g., 745A and 745B). In some embodiments, the wide portions 740 and the CDTI structure 720 are formed with wet etching. As explained in FIG. 6, wet-etching the semiconductor substrate 705 can reduce the cost of fabricating the image sensor and may be beneficial by reducing dark current. In some embodiments, such as that illustrated in FIG. 7, a first width of the wide portion 640 tapers to a second width of the narrow portion 645 at a first taper angle A1. The second width tapers at a second taper angle A2. In some embodiments, the first taper angle A1 is greater than the second taper angle A2. In some embodiments, the CDTI structure 720 tapers as the CDTI structure 720 extends into the semiconductor substrate 705 at a third taper angle A3. In some embodiments, the first taper angle A1 may be substantially equal (e.g., within 10% or otherwise based on the variance attributed to the fabrication process) to the third taper angle A3.

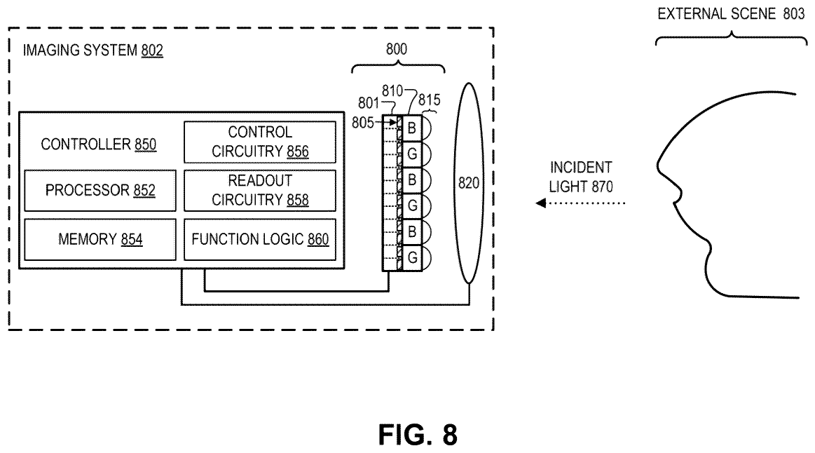

FIG. 8 is a functional block diagram of an imaging system 802 including an image sensor 800, in accordance with embodiments of the present disclosure. Imaging system 802 is capable of focusing on a point of interest (POI) within an external scene 803 in response to incident light 870. Imaging system 802 includes image sensor 800 to generate electrical or image signals in response to incident light 870, objective lens(es) 820 with adjustable optical power to focus on one or more points of interest within the external scene 803, and controller 850 to control, inter alia, operation of image sensor 800 and objective lens(es) 820. Image sensor 800 is one possible implementation of pixel cell 200, and pixels 300, 500, 600, and 700 as illustrated in FIGS. 2A-3A and FIGS. 5E-7 and includes a semiconductor material 801 forming a semiconductor substrate with a plurality of photodiodes 805 disposed within respective portions of the semiconductor material 801 arranged in an array form, a plurality of color filters 810, and a plurality of microlenses 815. The controller 850 includes one or more processors 852, memory 854, control circuitry 856, readout circuitry 858, and function logic 860.

The controller 850 includes logic and/or circuitry to control the operation (e.g., during pre-, post-, and in situ phases of image and/or video acquisition) of the various components of imaging system 802. The controller 850 may be implemented as hardware logic (e.g., application specific integrated circuits, field programmable gate arrays, system-on-chip, etc.), software/firmware logic executed on a general-purpose microcontroller or microprocessor, or a combination of both hardware and software/firmware logic. In one embodiment, the controller 850 includes the processor 852 coupled to memory 854 that store instructions for execution by the controller 850 or otherwise by one or more components of the imaging system 802. The instructions, when executed by the controller 850, may cause the imaging system 802 to perform operations that may associated with the various functional modules, logic blocks, or circuitry of the imaging system 802 including any one of, or a combination of, the control circuitry 856, the readout circuitry 858, the function logic 860, image sensor 800, objective lens 820, and any other element of imaging system 802 (illustrated or otherwise). The memory is a non-transitory computer-readable medium that may include, without limitation, a volatile (e.g., RAM) or non-volatile (e.g., ROM) storage system readable by controller 850. It is further appreciated that the controller 850 may be a monolithic integrated circuit, one or more discrete interconnected electrical components, or a combination thereof. Additionally, in some embodiments the one or more electrical components may be coupled to one another to collectively function as the controller 850 for orchestrating operation of the imaging system 802.

Control circuitry 856 may control operational characteristics of the image pixel array 805 (e.g., exposure duration, when to capture digital images or videos, and the like). Readout circuitry 858 reads or otherwise samples the analog signal from the individual photodiodes (e.g., read out electrical signals generated by each of the plurality of photodiodes 805 in response to incident light to read out image signals to capture an image frame, and the like) and may include amplification circuitry, analog-to-digital (ADC) circuitry, image buffers, or otherwise. In the illustrated embodiment, readout circuitry 858 is included in controller 850, but in other embodiments readout circuitry 858 may be separate from the controller 850. In some embodiments, the electrical or image signals may be respectively stored as image data and may be manipulated by the function logic 860 (e.g., demosaic the image data, apply post image effects such as crop, rotate, remove red eye, adjust brightness, adjust contrast, or otherwise).

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. A pixel, comprising:
a semiconductor substrate including a first side and a second side opposite the first side;
a first deep trench isolation (DTI) structure and a second DTI structure, each extending from the first side of the semiconductor substrate towards the second side, the first DTI structure including a wide portion and a narrow portion extending from the wide portion such that the narrow portion is disposed between the wide portion and the second side of the semiconductor substrate, wherein a first width of the wide portion is greater than a second width of the narrow portion, and wherein the wide portion extends to a first depth from the first side of the semiconductor substrate;
a photodiode region disposed in the semiconductor substrate between the first DTI structure and the second DTI structure; and
a cell deep trench isolation (CDTI) structure disposed in the semiconductor substrate between the wide portion of the first DTI structure and the second DTI structure, wherein the CDTI structure extends to a second depth, and wherein the first depth and the second depth extend a substantially equal distance from the first side of the semiconductor substrate.

2. The pixel of claim 1, wherein the first width of the wide portion is substantially equal to a corresponding width of the CDTI structure.

3. The pixel of claim 1, wherein the first width is substantially uniform throughout the wide portion, and wherein the second width tapers towards the second side of the semiconductor substrate.

4. The pixel of claim 1, wherein the first width tapers to the second width at a first taper angle, wherein the second width tapers at a second taper angle, and wherein the first taper angle is greater than the second taper angle.

5. The pixel of claim 1, wherein the first width is between two to six times greater than the second width.

6. The pixel of claim 1, wherein the wide portion comprises a first edge and a second edge opposite the first edge, wherein the narrow portion comprises a first wall and a second wall opposite the first wall, wherein an interface between the wide portion and the narrow portion defines a first separation distance between the first edge and the first wall and a second separation distance between the second edge and the second wall.

7. The pixel of claim 6, wherein the narrow portion is centrally aligned with the wide portion such that the first separation distance is substantially equal to the second separation distance.

8. The pixel of claim 6, wherein the narrow portion is offset from the wide portion such that the first separation distance is different from the second separation distance.

9. The pixel of claim 6, wherein a corresponding width of the CDTI structure is greater than a combined width of the first separation distance and the second separation distance.

10. The pixel of claim 6, wherein the second DTI structure comprises:
a second wide portion and a second narrow portion extending from the second wide portion such that the second narrow portion is disposed between the second wide portion and the second side of the semiconductor substrate, wherein a third width of the second wide portion is greater than a fourth width of the second narrow portion, and wherein the second wide portion extends to a third depth substantially equal to the first depth and the second depth.

11. The pixel of claim 10, wherein the second wide portion includes a third edge and a fourth edge opposite the third edge, wherein the second narrow portion includes a third wall and a fourth wall opposite the third wall, wherein an interface between the second wide portion and the second narrow portion defines a third separation distance between the third edge and the third wall and a fourth separation distance between the fourth edge and the fourth wall, wherein the first separation distance is greater than the second separation distance, and wherein the third separation distance is greater than the fourth separation distance.

12. The pixel of claim 1, wherein an aspect ratio corresponding to the first width with respect to a total depth the first DTI extends into the semiconductor substrate from the first side of the semiconductor substrate is at least 15.

13. A pixel cell, comprising:
a semiconductor substrate comprising a first side and a second side opposite the first side;
a first deep trench isolation (DTI) structure extending from the first side of the semiconductor substrate towards the second side, the first DTI structure including a wide portion and a narrow portion extending from the wide portion such that the narrow portion is disposed between the wide portion and the second side of the semiconductor substrate, wherein a first width of the wide portion is greater than a second width of the narrow portion, wherein the wide portion extends to a first depth from the first side of the semiconductor substrate;
a non-visible light pixel formed in or on the semiconductor substrate, the non-visible color pixel including:
a first photodiode region disposed in the semiconductor substrate proximate to the first DTI structure; and
a cell deep trench isolation (CDTI) structure disposed in the semiconductor substrate and extending from the first side to a second depth substantially equal to the first depth, wherein the CDTI structure is further disposed along an optical path of an incident light to the first photodiode region; and
a visible color pixel formed in or on the semiconductor substrate and adjacent to the non-visible light pixel, the visible color pixel including:
a second photodiode region disposed in the semiconductor substrate proximate to the first DTI structure such that the first DTI structure is disposed between the non-visible color pixel and the visible color pixel.

14. The pixel cell of claim 13, wherein the visible color pixel does not include a CDTI structure.

15. The pixel cell of claim 13, wherein the first width of the wide portion is substantially equal to a corresponding width of the CDTI structure.

16. The pixel cell of claim 13, wherein the first width is substantially uniform throughout the wide portion, and wherein the second width tapers towards the second side of the semiconductor substrate.

17. The pixel cell of claim 13, wherein the first width tapers to the second width at a first taper angle, wherein the second width tapers at a second taper angle, and wherein the first taper angle is greater than the second taper angle.

18. The pixel cell of claim 13, wherein the first width is between two to six times greater than the second width.

19. A method of manufacturing a pixel, the method comprising:
forming a photodiode region in a semiconductor substrate having a first side and a second side opposite the first side;
forming a first patterned layer of photoresist onto the first side of the semiconductor substrate;
etching into the semiconductor substrate to form a first wide trench, a second wide trench, and a third wide trench, each extending a first depth from the first side of the semiconductor substrate, and wherein the second wide trench is disposed between the first wide trench and the third wide trench and further disposed over the photodiode region;
forming a second patterned layer of photoresist onto the first side of the semiconductor substrate, wherein the second patterned layer of photoresist completely fills the second wide trench but only partially fills the first wide trench and the third wide trench;
etching a first narrow trench and a second narrow trench through openings of the second patterned layer of photoresist respectively overlapping with the first wide trench and the third wide trench such that a first narrow trench extends from the first wide trench toward the second side of the semiconductor substrate and the second narrow trench extends from the third wide trench toward the second side of the semiconductor substrate; and
filling, with one or more fill materials, the first wide trench and the first narrow trench to form a first deep trench isolation (DTI) structure, the second wide trench and the second narrow trench to form a second DTI structure, and the third wide trench to form a cell deep trench isolation (CDTI) structure wide trench,
wherein the first DTI structure includes a wide portion, formed from the first wide trench, and a narrow portion, formed from the first narrow trench, the first narrow trench extending from the wide portion such that the narrow portion is disposed between the wide portion and a second side of the semiconductor substrate, wherein a first width of the wide portion is greater than a second width of the narrow portion, and
wherein the wide portion and the CDTI structure each extends a substantially equal depth from the first side of the semiconductor substrate corresponding to the first depth.

20. The method of manufacturing the pixel of claim 19, wherein the first width of the wide portion is substantially equal to a corresponding width of the CDTI structure.
